(19) United States
(12) Patent Application Publication
(10) Pub. No.: US 2025/0081572 A1
(43) Pub. Date: Mar. 6, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yu-Chang LIN, Hsinchu (TW); Po-Kang HO, Taoyuan (TW); Liang-Yin CHEN, Hsinchu (TW); Tsai-Yu HUANG, Hsinchu (TW); Chi On CHUI, Hsinchu (TW)

(21) Appl. No.: 18/403,692

(22) Filed: Jan. 3, 2024

Related U.S. Application Data
(60) Provisional application No. 63/536,774, filed on Sep. 6, 2023.

(51) Int. Cl. H01L 29/66; H01L 21/265; H01L 21/324; H01L 29/06; H01L 29/423; H01L 29/775; H01L 29/786

(52) U.S. Cl. CPC H10D 64/018; H01L 21/265; H01L 21/324; H10D 30/014; H10D 30/43; H10D 30/6735; H10D 30/6757; H10D 62/121; H10D 64/017; H10D 64/021

(57) ABSTRACT

A semiconductor device structure and methods of forming the same are described. The structure includes a first semiconductor material disposed over a substrate and a dielectric layer disposed on the first semiconductor material. The dielectric layer includes a dopant. The structure further includes a second semiconductor material disposed on the dielectric layer, a first semiconductor layer in contact with the second semiconductor material, and a first dielectric spacer in contact with the first semiconductor layer, wherein the first dielectric spacer includes the dopant.

### CROSS-REFERENCE TO RELATED APPLICATIONS

This application claims priority to U.S. Provisional Application Ser. No. 63/536,774 filed Sep. 6, 2023, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6-18 are cross-sectional side views of various stages of manufacturing the semiconductor device structure taken along line A-A of FIG. 5, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide semiconductor device structures having a dielectric layer disposed between two semiconductor materials in a source/drain region. An implantation process and an anneal process is performed on the dielectric layer prior to a wet clean process. As a result, the wet etch rate (WER) of the dielectric layer is reduced, and the thickness of the dielectric layer is increased. The thicker dielectric layer can lead to reduced currently leakage.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

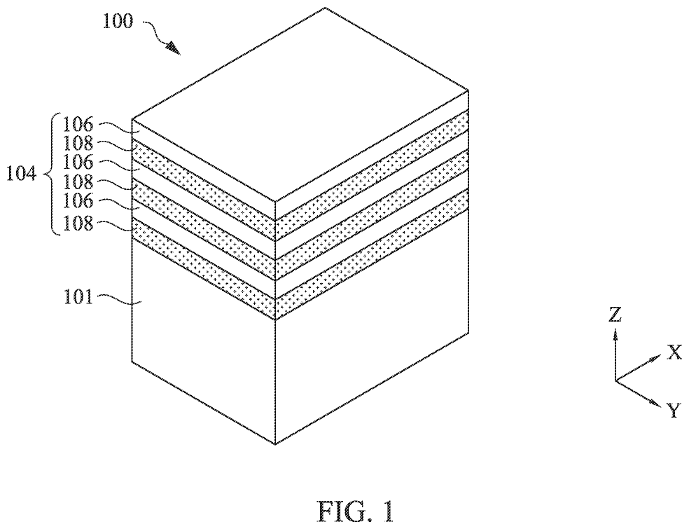

FIGS. 1-18 show exemplary processes for manufacturing a semiconductor device structure 100 according to embodiments of the present disclosure. It is understood that additional operations can be provided before, during, and after processes shown by FIGS. 1-18, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

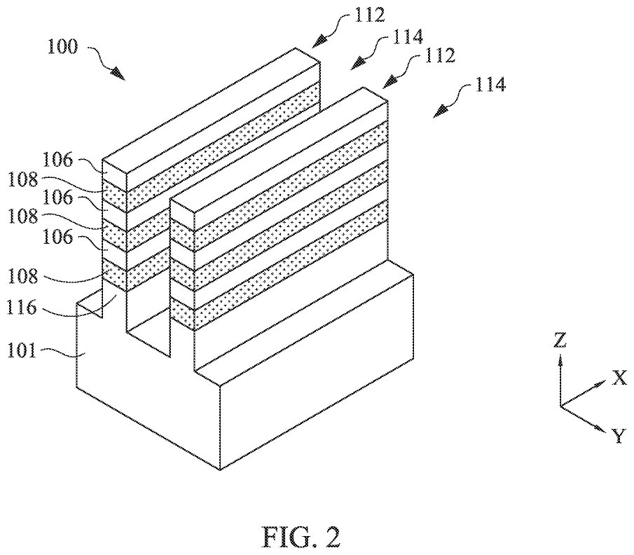

As shown in FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

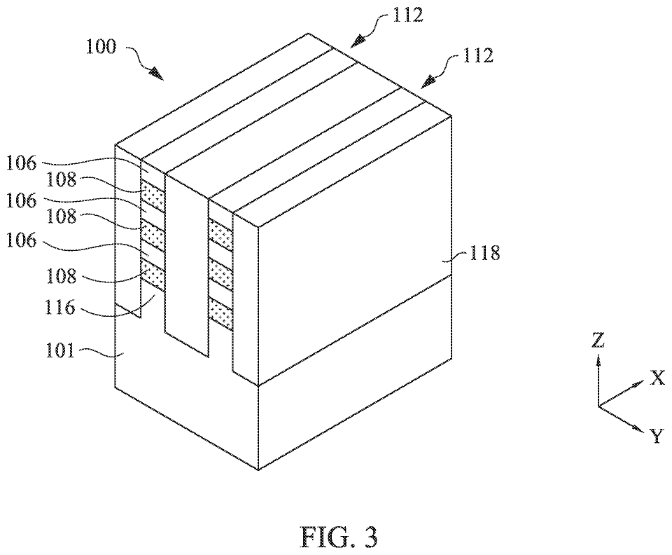

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

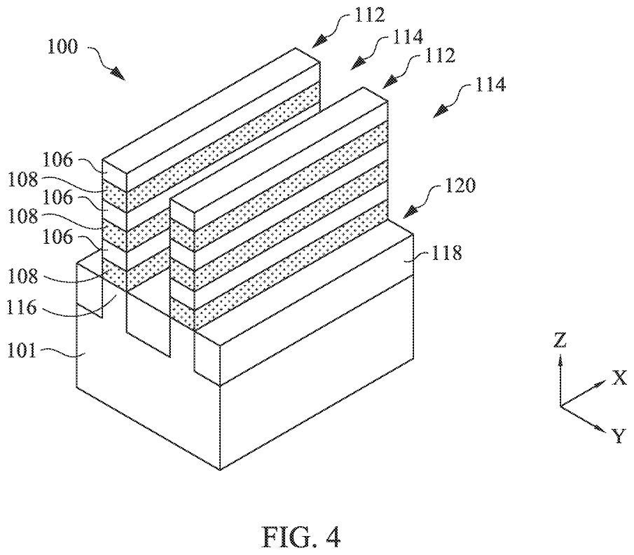

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the shallow trench isolation (STI) regions.

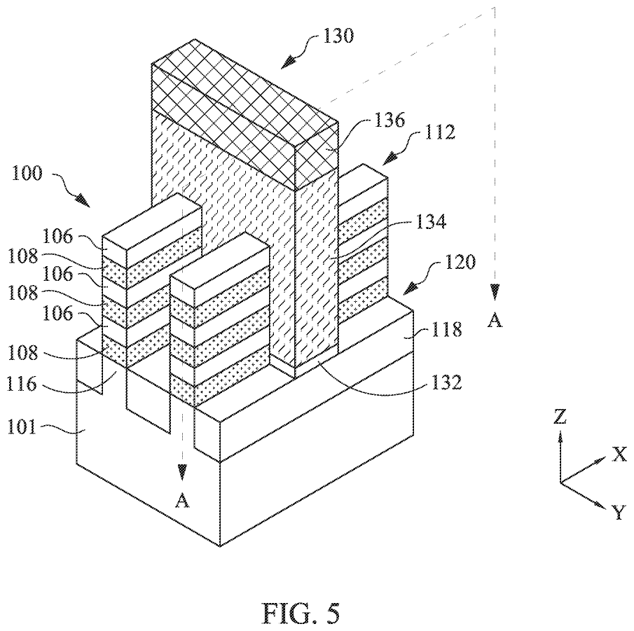

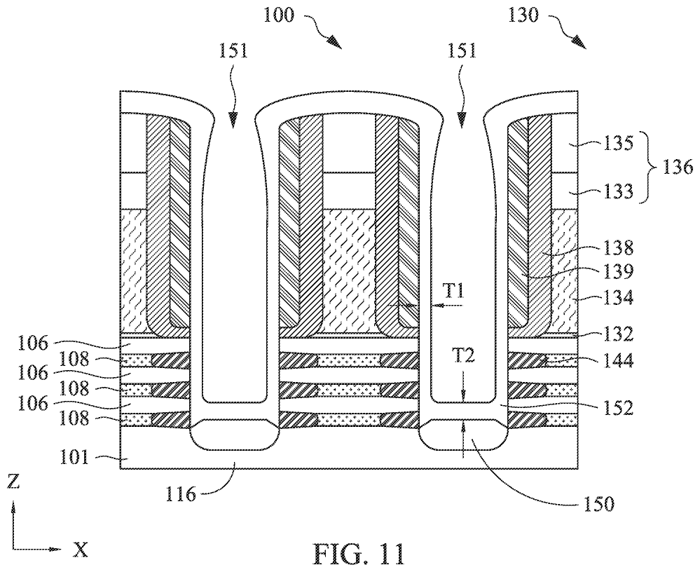

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments. In some embodiments, three sacrificial gate structures 130 are arranged along the X direction, as shown in FIGS. 11-15.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

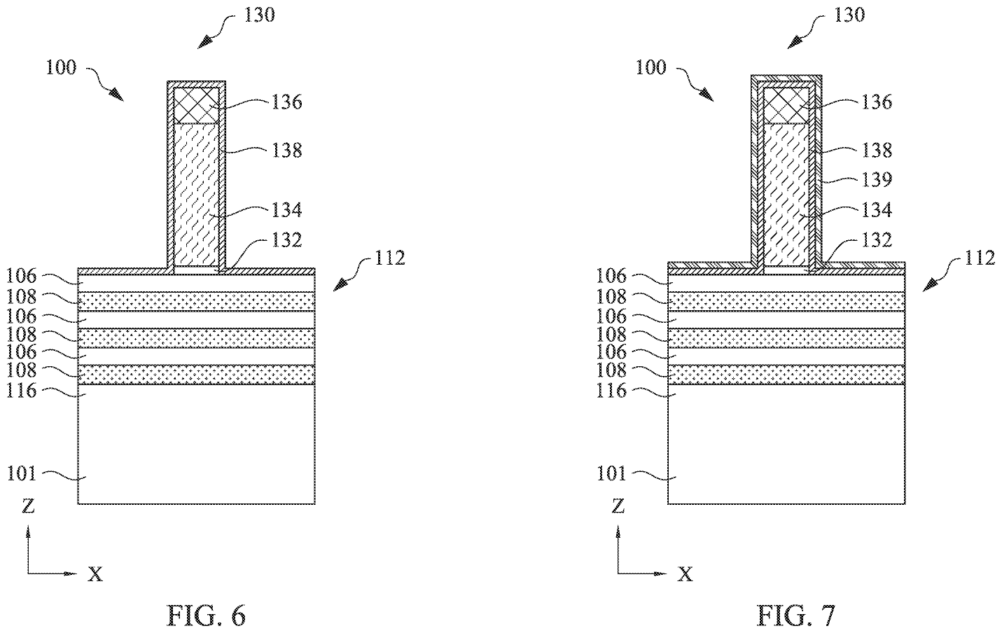

FIGS. 6-18 are cross-sectional side views of various stages of manufacturing the semiconductor device structure 100 taken along line A-A of FIG. 5, in accordance with some embodiments. As shown in FIG. 6, a first gate spacer 138 is deposited on the exposed surfaces of the semiconductor device structure 100. For example, the first gate spacer 138 is deposited on the fin structures 112, the isolation regions 120, and the sacrificial gate structure 130. The first gate spacer 138 may be made of a dielectric material such as silicon oxide, silicon nitride, silicon carbide, silicon oxynitride, SiCN, silicon oxycarbide, SiCON, and/or combinations thereof. The first gate spacer 138 may be formed by any suitable process. In some embodiments, the first gate spacer 138 is a conformal layer formed by a conformal process, such as an atomic layer deposition (ALD) process.

As shown in FIG. 7, a second gate spacer 139 is deposited on the first gate spacer 138. The second gate spacer 139 may include any suitable dielectric material, such as SiOₓ, SiON, SiN, SiCON, or SiCO. The second gate spacer 139 may have a thickness ranging from about 0.5 nm to about 5 nm. The second gate spacer 139 may be formed by any suitable process. In some embodiments, the second gate spacer 139 is deposited by CVD, PECVD, or electron cyclotron resonance CVD (ECR-CVD).

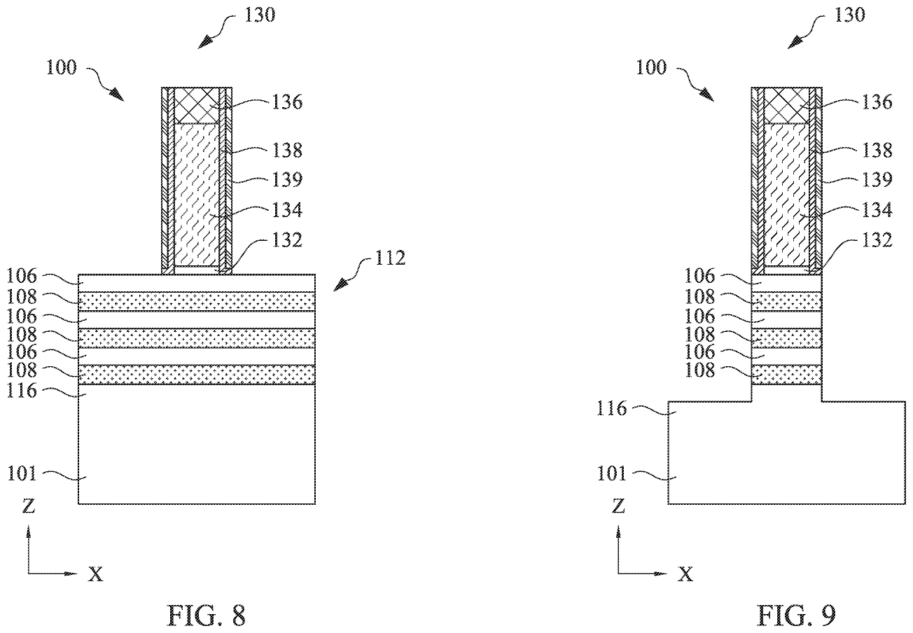

As shown in FIG. 8, horizontal portions of the first and second gate spacers 138, 139 are removed. In some embodiments, the horizontal portions of the first and second gate spacers 138, 139 are removed by an anisotropic etch process. The anisotropic etch process may be a selective etch process that does not substantially affect the mask layer 136, the stack of semiconductor layers 104, and the isolation regions 120.

As shown in FIG. 9, the portions of the fin structures 112 not covered by the sacrificial gate structure 130 and the first and second gate spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant. The well portions 116 are exposed on opposite sides of the sacrificial gate structure 130, as shown in FIG. 9.

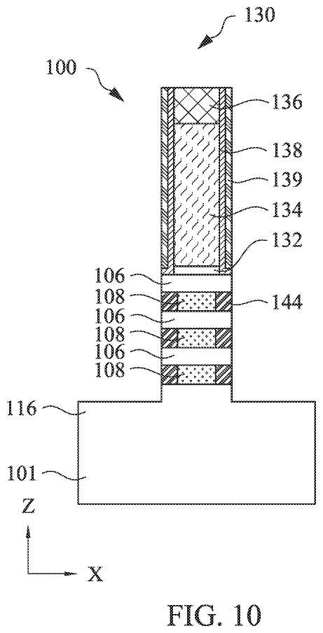

As shown in FIG. 10, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

As shown in FIG. 11, trenches 151 are formed between adjacent stacks of semiconductor layers and between adjacent sacrificial gate structures 130. As described above, in some embodiments, the mask layer 136 includes an oxide layer 133 and a nitride layer 135. A first semiconductor material 150 is formed on the exposed well portions 116 located at the bottoms of the trenches 151. In some embodiments, the first semiconductor material 150 includes undoped silicon or undoped SiGe. The first semiconductor material 150 may be first formed on semiconductor surfaces, such as on the exposed well portions 116 and on the first semiconductor layers 106, by epitaxy. A subsequent etch process is performed to remove the portions of the first semiconductor material 150 formed on the first semiconductor layers 106. The first semiconductor material 150 formed on the exposed well portions 116 may form a concave top surface as the result of the etch process. In some embodiments, the first semiconductor material 150 has a thickness ranging from about 5 nm to about 50 nm along the Z direction.

Next, as shown in FIG. 11, a dielectric layer 152 is formed on the semiconductor device structure 100. The dielectric layer 152 is formed in the trenches 151 and over the sacrificial gate structures 130 and the first and second gate spacers 138, 139. The dielectric layer 152 may include any suitable dielectric material. In some embodiments, the dielectric layer 152 includes SiN. The dielectric layer 152 may be formed by any suitable process. In some embodiments, the dielectric layer 152 is formed by CVD. Portions of the dielectric layer 152 formed on vertical surfaces may have a first thickness T1, and portions of the dielectric layer 152 formed on horizontal surfaces may have a second thickness T2 substantially greater than the first thickness T1. In some embodiments, the dielectric layer 152 includes a sidewall portion that is disposed on the vertical surfaces inside of each trench 151 and a bottom portion disposed on the first semiconductor material 150. For example, the sidewall portion of the dielectric layer 152 may be formed on the vertical surfaces of the dielectric spacers 144, the first semiconductor layers 106, and the first and second gate spacers 138, 139, as shown in FIG. 11. In some embodiments, the sidewall portion of the dielectric layer 152 has the thickness T1, and the bottom portion of the dielectric layer 152 has the thickness T2 substantially greater than the first thickness T1. In some embodiments, the width of the trench 151 in the X direction ranges from about 22 nm to about 26 nm, and the thickness T2 may be greater than about 5 nm and less than about 10 nm. If the thickness T2 is greater than about 10 nm, the dielectric layer 152 may be connected at the top of the trench 151. In other words, the dielectric layer 152 may seal the trench 151 with a void formed therein. The bottom portion of the dielectric layer 152 may function as an isolation layer to prevent current leakage through the portion of the well portion 116 located below the bottommost second semiconductor layer 108. Thus, if the thickness T2 is less than about 5 nm, the bottom portion of the dielectric layer 152 may be too thin to function sufficiently as an isolation layer.

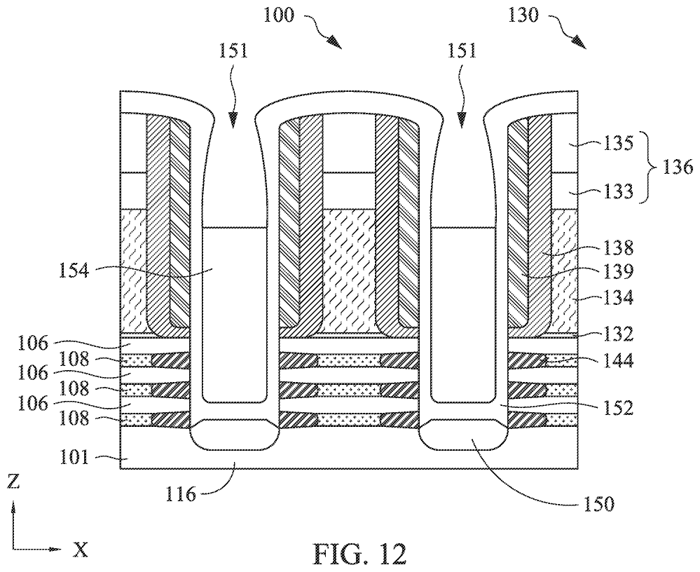

As shown in FIG. 12, a mask layer 154 is formed on the dielectric layer 152 and partially fills the trenches 151. The mask layer 154 may be a bottom antireflective coating (BARC) layer. The mask layer 154 may be formed by first forming a layer that completely fills the trenches 151 and over the sacrificial gate structures 130, and the layer is then recessed to form the mask layer 154. In some embodiments, the mask layer 154 may be recessed by a selective etch process that does not substantially affect the dielectric layer 152. The selective etch process may be a dry etch, a wet etch, or a combination thereof. In some embodiments, the selective etch process is a wet etch. The mask layer 154 is in contact with a first portion of the sidewall portion of the dielectric layer 152 in the trenches 151, and a second portion of the sidewall portion of the dielectric layer 152 in the trenches 151 is exposed. In some embodiments, the top surface of the mask layer 154 in the trench 151 is located at a level between the top surface and the bottom surface of the sacrificial gate electrode layer 134, as shown in FIG. 12. In some embodiments, the top surface of the mask layer 154 in the trench 151 is located at a level below the bottom surface of the sacrificial gate electrode layer 134, such as at a level below the topmost first semiconductor layer 106, for example between the top surface and the bottom surface of the second first semiconductor layer 106 from the bottom. The sidewall portion of the dielectric layer 152 is to be removed in subsequent processes, and the bottom portion of the dielectric layer 152 is to be remained. Thus, the mask layer 154 protects the bottom portion of the dielectric layer 152 during the subsequent removal of the second portion of the sidewall portion and the subsequent recessing of the first portion of the sidewall portion of the dielectric layer 152.

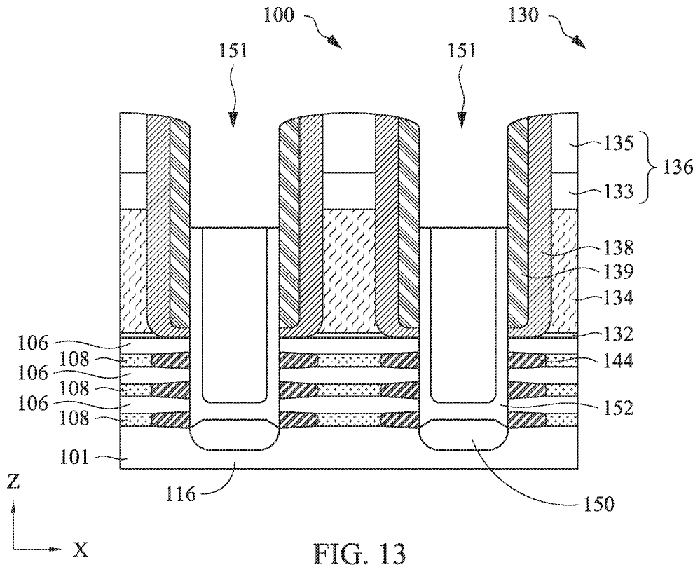

As shown in FIG. 13, the exposed second portion of the sidewall portion of the dielectric layer 152 in each trench 151 and portions of the dielectric layer 152 located over the sacrificial gate structures 130 and the first and second gate spacers 138, 139 are removed. The portions of the dielectric layer 152 may be removed by a selective etch process, such as a dry etch, a wet etch, or a combination thereof. The selective etch process removes the exposed second portion of the sidewall portion of the dielectric layer 152 but does not substantially affect the mask layer 154, the first and second gate spacers 138, 139, and the mask layer 136. The remaining first portion of the sidewall portion of the dielectric layer 152 located in the trench 151 may include a top surface substantially coplanar with a top surface of the mask layer 154, as shown in FIG. 13.

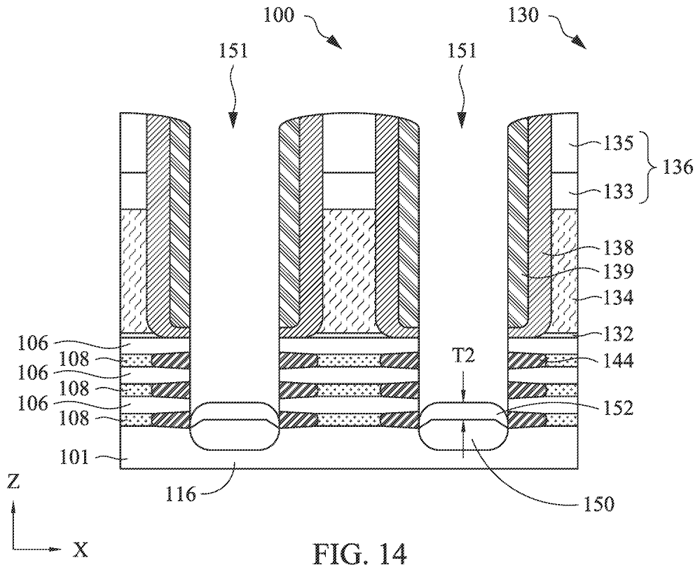

As shown in FIG. 14, the mask layer 154 and the first portion of the sidewall portion of the dielectric layer 152 are removed. The mask layer 154 and the sidewall portion of the dielectric layer 152 may be removed by any suitable process. In some embodiments, the first portion of the sidewall portion of the dielectric layer 152 is first recessed by a selective etch process, and the recessed dielectric layer 152 has the top surface located substantially below the top surface of the mask layer 154. The selective etch process recesses the dielectric layer 152 but does not substantially affect the mask layer 136, the first and second gate spacers 138, 139, and the mask layer 154. In some embodiments, the top surface of the recessed dielectric layer 152 is located at a level between the top surface and the bottom surface of the bottommost first semiconductor layer 106. In some embodiments, the selective etch process to recess the first portion of the sidewall portion of the dielectric layer 152 and the selective etch process to remove the exposed second portion of the sidewall portion of the dielectric layer 152 are the same selective etch process. In other words, a single selective etch process is performed to remove the exposed second portion of the sidewall portion of the dielectric layer 152 and to recess the first portion of the sidewall portion of the dielectric layer 152.

Next, the mask layer 154 is removed. The mask layer 154 may be removed by a selective process. In some embodiments, the mask layer 154 is removed using a stripping process, such as using a solvent or an oxygen plasma. The selective process to remove the mask layer 154 does not substantially affect the mask layer 136, the first and second gate spacers 138, 139, the first semiconductor layers 106, the dielectric spacers 144, and the dielectric layer 152. After the removal of the mask layer 154, the dielectric layer 152 includes the sidewall portion, which is the recessed first portion of the sidewall portion, and the bottom portion. As described above, the top surface of the sidewall portion of the dielectric layer 152 may be located at a level between the top surface and the bottom surface of the bottommost first semiconductor layer 106.

Next, an etch process is performed to remove the sidewall portion of the dielectric layer 152, while the bottom portion of the dielectric layer 152 remains. As described above, the sidewall portion of the dielectric layer 152 has the thickness T1, which is substantially less than the thickness T2 of the bottom portion of the dielectric layer 152. As a result, the etch process completely removes the sidewall portion of the dielectric layer 152, while the thickness T2 of the bottom portion of the dielectric layer 152 is reduced. In some embodiments, the thickness T2 of the bottom portion of the dielectric layer 152 after the removal of the sidewall portion of the dielectric layer 152 ranges from about 5 nm to about 8 nm. The etch process may be any suitable etch process, such as a dry etch process, a wet etch process, or a combination thereof.

After the etch process to remove the sidewall portion of the dielectric layer 152, the dielectric layer 152 (the remaining bottom portion) is disposed on the first semiconductor material 150, as shown in FIG. 14. Next, an implantation process followed by an annealing process are performed on the dielectric layer 152 to decrease the WER of the dielectric layer 152. In some embodiments, the implantation process includes implanting a dopant in the dielectric layer 152. For example, the dielectric layer 152 includes SiN, and the dopant may include Si, F, B, or any suitable dopant. A dopant gas, such as a silicon-containing gas, a fluorine-containing gas, or a boron-containing gas, may be utilized during the implantation process. The implantation process may have an implantation energy ranging from about 0.2 keV to about 5 keV, an implantation temperature ranging from about −60 degrees Celsius to about 450 degrees Celsius, an implantation tilt angle ranging from about 0 degrees to about 15 degrees, and a substrate rotation ranging from about 0 degrees to about 360 degrees. The dopant concentration may range from about 5×10²¹ cm⁻³ to about 1×10²¹ cm⁻³. As described above, the implantation process decreases the WER of the dielectric layer 152. Thus, if the dopant concentration of the dielectric layer 152 is less than about 5×10²¹ cm⁻³, the WER of the dielectric layer 152 is not reduced, and the thickness of the dielectric layer 152 is substantially reduced during the subsequent wet clean process. On the other hand, if the dopant concentration of the dielectric layer 152 is greater than about 1×10²¹ cm⁻³, the quality of the subsequently formed second semiconductor material 156 may be negatively affected. In some embodiments, the dopant concentration of the dielectric layer 152 increases in a direction away from the first semiconductor material 150.

In some embodiments, the dielectric layer 152 has a first silicon concentration before the implantation process. The first silicon concentration may be substantially uniform in the dielectric layer 152. After the implantation process, in the embodiment wherein the dopant is silicon, the dielectric layer 152 has a second silicon concentration substantially greater than the first silicon concentration. In some embodiments, the dopant is B or F, and the dielectric layer 152 is substantially free of the dopant prior to the implantation process. After the implantation process, the dopant has a concentration profile that increases from a bottom surface of the dielectric layer 152 to a top surface of the dielectric layer 152.

In some embodiments, the exposed layers, such as the first and second gate spacers 138, 139, the first semiconductor layers 106, and the dielectric spacers 144, may also be doped with the dopant from the implantation process. As a result, in some embodiments, the first and second gate spacers 138, 139, the first semiconductor layers 106, and the dielectric spacers 144 include the dopant located at the corresponding surfaces exposed in the trenches 151. In some embodiments, the dopant is Si, and the concentration of silicon in the first and second gate spacers 138, 139, the first semiconductor layers 106, and the dielectric spacers 144 is substantially greater at and near the corresponding surfaces exposed in the trenches 151 compared to the concentration of silicon located in other regions of the first and second gate spacers 138, 139, the first semiconductor layers 106, and the dielectric spacers 144. In other words, the dopant concentration of the first and second gate spacers 138, 139, the first semiconductor layers 106, and the dielectric spacers 144 decreases in a direction away from the trench 151. In some embodiments, the dopant diffuses through the dielectric layer 152 and into the first semiconductor material 150. As a result, the first semiconductor material 150 may include the dopant near the interface between the first semiconductor material 150 and the dielectric layer 152.

After the implantation process, an annealing process is performed to drive out hydrogen to densify the dielectric layer 152. The annealing process may be any suitable annealing process. In some embodiments, the annealing process may be a flash lamp annealing (FLA), laser spike annealing (LSA), or rapid thermal annealing (RTA). The annealing temperature may range from about 1050 degrees Celsius to about 1200 degrees Celsius for FLA or LSA, and from about 600 degrees Celsius to about 1000 degrees Celsius for RTA. The dwell time of the annealing process may range from about 0.1 ms to about 40 ms for FLA or LSA, and from about 1 s to about 20 s for RTA. The chamber pressure may range from about 1 torr to about 760 torr during the annealing process.

As a result of the implantation process and the annealing process, the dielectric layer 152 shown in FIG. 14 has a decreased WER. In some embodiments, the WER is improved by 75 percent. The implantation process and the annealing process are not performed prior to the formation of the dielectric layer 152 as shown in FIG. 14. In other words, the implantation process and the annealing process are performed after the removal of the sidewall portion of the dielectric layer 152. For example, if the implantation process and the annealing process are performed after the deposition of the dielectric layer 152 as shown in FIG. 11, the dopant in the dielectric layer 152 may cause the sidewall portion of the dielectric layer 152 more difficult to remove.

After the implantation process and the annealing process, a wet clean process is performed to remove native oxides and other contaminants from the semiconductor device structure 100. The wet clean process may use any suitable solution, such as de-ionized water (DI), SC1 (DI, NH₄OH, and/or H₂O₂), SC2 (DI, HCl, and/or H₂O₂), ozonated de-ionized water (DIWO₃), SPM (H₂SO4 and/or H₂O₂), SOM (H₂SO₄ and/or O₃), SPOM, H₃PO₄, dilute hydrofluoric acid (DHF), HF, HF/ethylene glycol (EG), HF/HNO₃, NH₄OH, or tetramethylammonium hydroxide (TMAH). The dielectric layer 152 is not substantially affected by the wet clean process due to the decreased WER as a result of the implantation process and the annealing process. Without the implantation process and the annealing process, the thickness of the dielectric layer 152 may be reduced substantially by the wet clean process, which may lead to current leakage. In some embodiments, the wet clean process can reduce the thickness of the dielectric layer 152 by 1 nm or more, if the implantation process and the annealing process are not performed on the dielectric layer 152. In some embodiments, the thickness T2 of the dielectric layer 152 after the wet clean process ranges from about 2 nm to about 5 nm. In some embodiments, the bottom surface of the dielectric layer 152 may be located at the same level as the bottom surface of the dielectric spacer 144, and the thickness T2 of the dielectric layer 152 may be about 50 percent to about 80 percent of the thickness of the dielectric spacer 144. If the thickness T2 of the dielectric layer 152 is less than about 50 percent of the thickness of the dielectric spacer 144, the dielectric layer 152 may be too thin to prevent current leakage. On the other hand, if the thickness T2 of the dielectric layer 152 is greater than about 80 percent of the thickness of the dielectric spacer 144, the quality of the second semiconductor material 156 may be negatively affected since the dielectric layer 152 is too close to the first semiconductor layer 106. In some embodiments, the dielectric layer 152 has a varying thickness as a result of the wet clean process. For example, an edge portion of the dielectric layer 152 adjacent the dielectric spacer 144 may be thinner than a center portion of the dielectric layer 152. In some embodiments, the thickness of the edge portion of the dielectric layer 152 ranges from about 1.5 nm to about 2.5 nm, and the thickness of the center portion of the dielectric layer 152 ranges from about 3 nm to about 4 nm.

In some embodiments, the distance along the Z direction from the bottom surface of the bottommost first semiconductor layer 106 to the top surface of the topmost first semiconductor layer 106 ranges from about 30 nm to about 60 nm, and the distance from the top surface of the topmost first semiconductor layer 106 to the top surface of the nitride layer 135 may range from about 120 nm to about 150 nm.

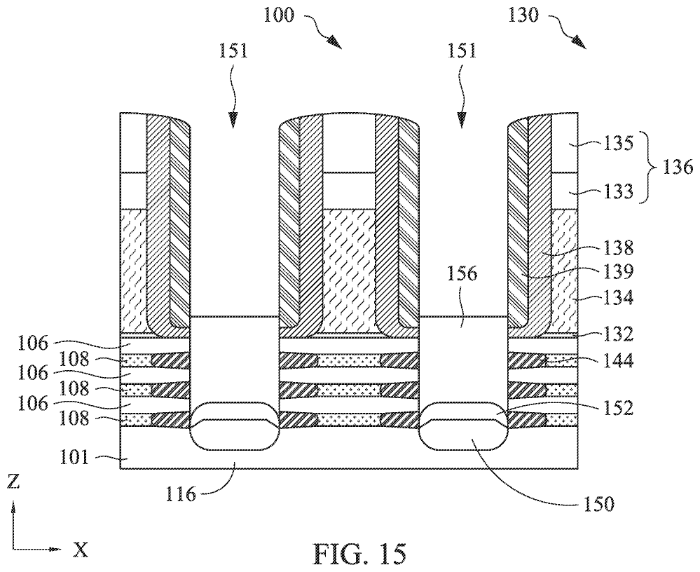

As shown in FIG. 15, a second semiconductor material 156 is formed in the trenches 151, and the second semiconductor material 156 may be epitaxially grown from the first semiconductor layers 106. The second semiconductor material 156 may grow both vertically and horizontally to form facets, which may correspond to crystalline planes of the material used for the first semiconductor layer 106. The second semiconductor material 156 may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. The second semiconductor material 156 may be made of one or more layers of Si, SiP, SiC and SiCP for n-channel FETs or Si, SiGe, Ge for p-channel FETs. For p-channel FETs, p-type dopants, such as boron (B), may also be included in the second semiconductor material 156. The second semiconductor material 156 may be formed by an epitaxial growth method using CVD, ALD or MBE.

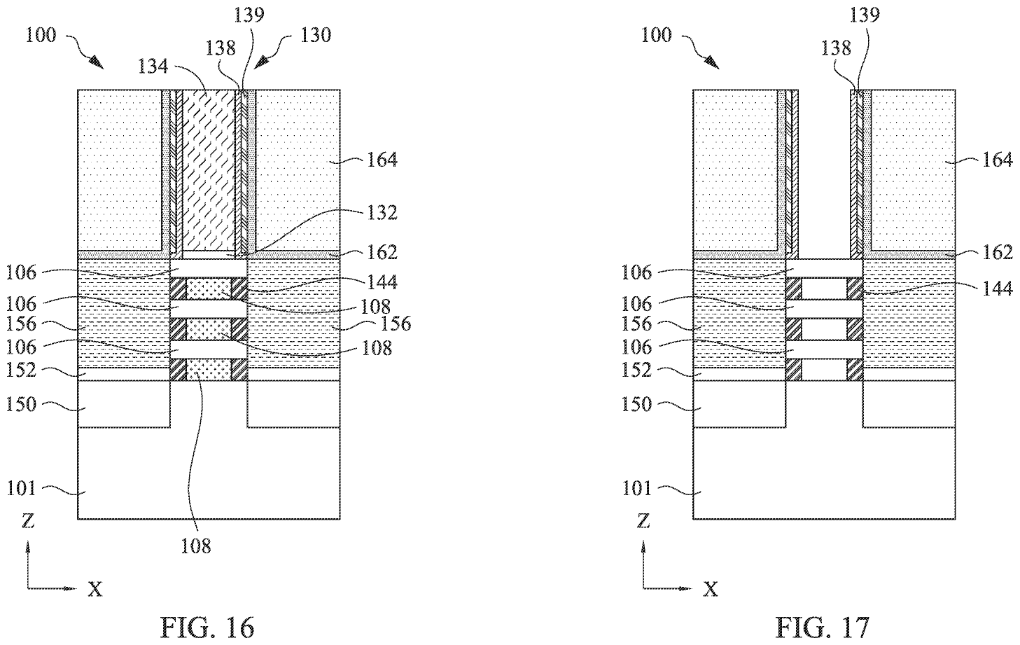

As shown in FIG. 16, a contact etch stop layer (CESL) 162 is conformally formed on the exposed surfaces of the semiconductor device structure 100. The CESL 162 covers the second gate spacer 139, the isolation regions 120, and the second semiconductor material 156. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 16. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 16.

As shown in FIG. 17, the sacrificial gate structure 130 and the second semiconductor layers 108 are removed. The removal of the sacrificial gate structure 130 and the semiconductor layers 108 forms an opening between the first gate spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

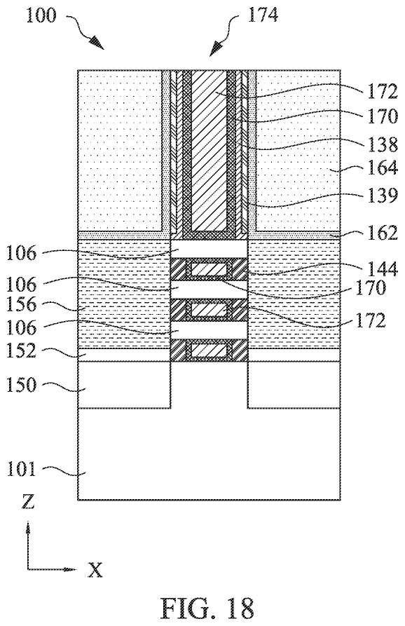

As shown in FIG. 18, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high- K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

It is understood that the semiconductor device structure 100 may undergo further processes to form conductive contacts in the ILD layer 164 to be electrically connected to the second semiconductor material 156 and to form conductive contacts to be electrically connected to the gate electrode layer 172. An interconnect structure may be formed over the semiconductor device structure 100 to provide electrical paths to the devices formed on the substrate 101.

Embodiments of the present disclosure provide a semiconductor device structure including a dielectric layer 152 disposed between the first semiconductor material 150 and the second semiconductor material 156. An implantation process is performed to implant a dopant into the dielectric layer 152, and the implantation process may also implant the dopant into the first gate spacer 138, the dielectric spacers 144, and the first semiconductor layers 106. Some embodiments may achieve advantages. For example, the dielectric layer 152 including the dopant has a reduced WER. As a result, the thickness of the dielectric layer 152 is not substantially affected by a wet clean process, which in turn prevents current leakage.

An embodiment is a semiconductor device structure. The structure includes a first semiconductor material disposed over a substrate and a dielectric layer disposed on the first semiconductor material. The dielectric layer includes a dopant. The structure further includes a second semiconductor material disposed on the dielectric layer, a first semiconductor layer in contact with the second semiconductor material, and a first dielectric spacer in contact with the first semiconductor layer, wherein the first dielectric spacer includes the dopant.

Another embodiment is a method. The method includes forming a sacrificial gate stack over a portion of a fin structure, removing an exposed portion of the fin structure to expose a portion of a substrate and a surface of a semiconductor layer of the fin structure, depositing a first semiconductor material on the exposed portion of the substrate, and depositing a dielectric layer. The dielectric layer includes a bottom portion disposed on the first semiconductor material and a sidewall portion disposed on the surface of the semiconductor layer. The method further includes removing the sidewall portion of the dielectric layer, performing an implantation process to implant a dopant in the bottom portion of the dielectric layer, then performing an annealing process on the bottom portion of the dielectric layer, and forming a second semiconductor material on the bottom portion of the dielectric layer.

A further embodiment is a method. The method includes forming a fin structure from a substrate, and the fin structure includes a first plurality of semiconductor layers and a second plurality of semiconductor layers. The method further includes forming a sacrificial gate stack over the fin structure, depositing a gate spacer on the sacrificial gate stack, removing portions of the fin structure to expose a portion of the substrate, recessing the second plurality of semiconductor layers to form cavities, forming dielectric spacers in the cavities, depositing a first semiconductor material on the exposed portion of the substrate, and depositing a dielectric layer. The dielectric layer includes a sidewall portion in contact with the gate spacer, the first plurality of semiconductor layers, and the dielectric spacers and a bottom portion in contact with the first semiconductor material. The method further includes removing the sidewall portion of the dielectric layer, performing an implantation process to implant a dopant in the bottom portion of the dielectric layer, then performing an annealing process on the bottom portion of the dielectric layer, and forming a second semiconductor material on the bottom portion of the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor material disposed over a substrate;
a dielectric layer disposed on the first semiconductor material, wherein the dielectric layer includes a dopant;
a second semiconductor material disposed on the dielectric layer;
a first semiconductor layer in contact with the second semiconductor material; and
a first dielectric spacer in contact with the first semiconductor layer, wherein the first dielectric spacer includes the dopant.

2. The semiconductor device structure of claim 1, wherein the dopant comprises Si, F, or B.

3. The semiconductor device structure of claim 1, wherein a dopant concentration of the dielectric spacer decreases in a direction away from the second semiconductor material.

4. The semiconductor device structure of claim 3, wherein a dopant concentration of the dielectric layer increases in a direction away from the first semiconductor material.

5. The semiconductor device structure of claim 1, further comprising a second semiconductor layer in contact with the second semiconductor material, wherein the second semiconductor layer is disposed over the first semiconductor layer, and the first dielectric spacer is disposed between the first and second semiconductor layers.

6. The semiconductor device structure of claim 5, further comprising a second dielectric spacer in contact with the second semiconductor layer, wherein the second dielectric spacer and the first and second semiconductor layers are doped with the dopant.

7. The semiconductor device structure of claim 1, wherein a thickness of the dielectric layer is about 50 percent to about 80 percent of a thickness of the first dielectric spacer, and a top surface of the dielectric layer is located below a bottom surface of the first semiconductor layer.

8. A method, comprising:
forming a sacrificial gate stack over a portion of a fin structure;
removing an exposed portion of the fin structure to expose a portion of a substrate and a surface of a semiconductor layer of the fin structure;
depositing a first semiconductor material on the exposed portion of the substrate;
depositing a dielectric layer, wherein the dielectric layer comprises a bottom portion disposed on the first semiconductor material and a sidewall portion disposed on the surface of the semiconductor layer;
removing the sidewall portion of the dielectric layer;
performing an implantation process to implant a dopant in the bottom portion of the dielectric layer; then
performing an annealing process on the bottom portion of the dielectric layer; and
forming a second semiconductor material on the bottom portion of the dielectric layer.

9. The method of claim 8, wherein a dopant concentration of the dielectric layer ranges from about 5×10²⁰ cm⁻³ to about 1×10²¹ cm⁻³.

10. The method of claim 8, wherein the implantation process implants the dopant in gate spacers formed along sidewalls of the sacrificial gate stack.

11. The method of claim 8, wherein the annealing process comprises flash lamp annealing (FLA), laser spike annealing (LSA), or rapid thermal annealing (RTA).

12. The method of claim 11, wherein the annealing process comprises FLA or LSA, an annealing temperature ranges from about 1050 degrees Celsius to about 1200 degrees Celsius, and a dwell time of the annealing process ranges from about 0.1 ms to about 40 ms.

13. The method of claim 11, wherein the annealing process comprises RTA, an annealing temperature ranges from about 600 degrees Celsius to about 1000 degrees Celsius, and a dwell time of the annealing process ranges from about 1 s to about 20 s.

14. The method of claim 8, wherein the bottom portion of the dielectric layer has a center portion having a first thickness and an edge portion having a second thickness substantially less than the first thickness.

15. The method of claim 14, further comprising a wet clean process after the annealing process and before the forming the second semiconductor material, wherein the thickness of the bottom portion of the dielectric layer ranges from about 2 nm to about 5 nm after the wet clean process.

16. A method, comprising:
forming a fin structure from a substrate, wherein the fin structure comprises a first plurality of semiconductor layers and a second plurality of semiconductor layers;
forming a sacrificial gate stack over the fin structure;
depositing a gate spacer on the sacrificial gate stack;
removing portions of the fin structure to expose a portion of the substrate;
recessing the second plurality of semiconductor layers to form cavities;
forming dielectric spacers in the cavities;
depositing a first semiconductor material on the exposed portion of the substrate;
depositing a dielectric layer, wherein the dielectric layer comprises a sidewall portion in contact with the gate spacer, the first plurality of semiconductor layers, and the dielectric spacers and a bottom portion in contact with the first semiconductor material;
removing the sidewall portion of the dielectric layer;
performing an implantation process to implant a dopant in the bottom portion of the dielectric layer; then
performing an annealing process on the bottom portion of the dielectric layer; and
forming a second semiconductor material on the bottom portion of the dielectric layer.

17. The method of claim 16, wherein the removing the sidewall portion of the dielectric layer comprises:
depositing a mask layer on the dielectric layer;
recessing the mask layer to expose a portion of the sidewall portion of the dielectric layer;
removing the exposed portion of the sidewall portion of the dielectric layer;
recessing a remaining sidewall portion of the dielectric layer;
removing the mask layer; and
removing the remaining sidewall portion.

18. The method of claim 17, further comprising a wet clean process after the annealing process and before the forming the second semiconductor material.

19. The method of claim 18, wherein a wet etch rate of the dielectric layer is reduced by the implantation process.

20. The method of claim 16, wherein the second semiconductor material is grown from the first plurality of semiconductor layers.
